(19) United States
(12) Patent Application Publication
(10) Pub. No.: US 2018/0234091 A1
(43) Pub. Date: Aug. 16, 2018

(54) METHOD AND CIRCUIT ARRANGEMENT FOR OPERATING AT LEAST ONE SEMICONDUCTOR SWITCH, METHOD, AND POWER CONVERTER FOR OPERATING AN ELECTRIC MACHINE

(71) Applicant: Conti Temic microelectronic GmbH, Nurnberg (DE)

(72) Inventors: Willi Ehrensperger, Neukirchen (DE); Christoph Hornstein, Nurnberg (DE); Kai Kühnen, Nurnberg (DE); Matthias Duchrau, Nurnberg (DE)

(73) Assignee: Conti Temic microelectronic GmbH, Nurnberg (DE)

(21) Appl. No.: 15/950,841

(22) Filed: Apr. 11, 2018

Related U.S. Application Data
(63) Continuation of application No. PCT/EP2016/073368, filed on Sep. 29, 2016.

(30) Foreign Application Priority Data
Oct. 13, 2015 (DE) 10 2015 219 774.3
Apr. 28, 2016 (DE) 10 2016 207 259.5

(51) Int. Cl. H03K 17/18; H03K 17/693; H04L 25/49; H03K 17/081; H02M 7/5387

(52) U.S. Cl. CPC H03K 17/18; H03K 17/693; H02M 7/53873; H03K 17/08104; H04L 25/4902

(57) ABSTRACT

A method for operating at least one semiconductor switch using at least one pulse-width-modulated driver signal is disclosed. Digital data are transmitted in a modulated manner on the pulse-width-modulated driver signal. The digital data includes information about measurement variables and/or reference/control variables and/or manipulated variables for operating the semiconductor switch.

### CROSS-REFERENCE TO RELATED APPLICATIONS

This application is a continuation of International application No. PCT/EP2016/073368 filed Sep. 29, 2016, which claims priority to German application No. 10 2015 219 774.3, filed on Oct. 13, 2015, and German application No. 10 2016 207 259.5 filed on Apr. 28, 2016, each of which is hereby incorporated by reference herein in its entirety.

### TECHNICAL FIELD

The disclosure relates to a method and to a circuit arrangement for operating at least one semiconductor switch using at least one pulse-width-modulated driver signal. The disclosure further relates to a method and to a converter for operating an electric machine having the mentioned circuit arrangement.

### BACKGROUND

Converters, such as inverters, having multiple, e.g., three, half-bridge circuits have positive-voltage-side semiconductor switches and negative-voltage-side semiconductor switches, which are switched on and off alternately or in opposite directions to one another by pulse-width-modulated driver signals. As a result, a polyphase, such as three-phase, alternating current (phase currents) that is used to operate an electric machine, for example, is generated from a DC supply current.

For better, in particular loss-optimized and fault-free, regulation and control of the electric machine, it is helpful for the alternating current or the phase currents to be adjusted depending on the state of the converter or the electric machine.

The present disclosure demonstrates an option that may be used to adjust the alternating current or the phase currents in a simple and cost-effective manner to the state of a converter having a semiconductor switch or of an electric machine to be operated using the converter such that, for example, the switching losses may be optimized and switching faults can be avoided.

### SUMMARY

One aspect of the disclosure provides a method for operating, for example, regulating or controlling, at least one semiconductor switch using at least one pulse-width-modulated driver signal. According to the method, digital data are modulated onto the pulse-width-modulated driver signal before the driver signal is transmitted for operating the semiconductor switch (for example of a converter). The digital data, which are transmitted in a modulated manner on the driver signal, include information about measurement values, reference/control variables and/or manipulated variables for operating the semiconductor switch.

Implementations of the disclosure may include one or more of the following optional features. In some implementations, the pulse-width-modulated driver signal has a signal level, a signal period duration and thus a signal frequency, as well as a duty cycle, which are able to be set depending on the operating state of the semiconductor switch, for example of a converter or of an electric machine to be operated using the semiconductor switch.

The digital data are modulated onto the driver signal in the form of a digital signal or in the form of bit sequences. The digital signal has a signal frequency that is higher in comparison to the signal frequency of the driver signal by a factor of at least 5, for example at least 10, at least 100, at least 1000.

By modulating the digital signal on the driver signal, the driver signal effectively serves as a carrier signal for the digital data.

Unlike conventional signal modulation, in which a “low-frequency” data signal is transmitted in a modulated manner on a “high-frequency” carrier signal, in the above method, a comparatively “high-frequency” digital signal is transmitted in a modulated manner on a driver signal that is “low-frequency” compared to the digital signal.

The digital data may include information about measurement variables, which may be, for example, measurement values for output currents (load path currents) of the semiconductor switch or phase currents or for a link circuit voltage of a converter having the semiconductor switch.

The digital data may further include information about reference/control variables. Reference and/or control values are the instantaneous values of the input variable for a control/regulation actuator of the converter having the semiconductor switch.

The digital data may also include information about manipulated variables, which may be output variables (the setting) of the actuator used in control and regulation technology and with the aid of which targeted intervention may be effected in the control or regulation path.

The fact that the information listed above is transmitted in a modulated manner on the driver signal as a digital signal dispenses with data connections, which would otherwise be required for transmitting this information, and hence also possible disturbances due to interruptions in the data connections. Fewer data connections in turn reduce the complexity of the converter and hence also the production costs of the converter.

This demonstrates an option that may be used to adjust the alternating current or the phase currents of a converter having a semiconductor switch in a simple and cost-effective manner to the state of the converter such that, for example, the switching losses may be optimized and switching faults may be avoided.

The method mentioned above may be used to operate a positive-voltage-side and a negative-voltage-side semiconductor switch of one and the same half-bridge circuit. In this case, the positive-voltage-side and/or the negative-voltage-side semiconductor switch are operated, in each case, by a first and a second pulse-width-modulated driver signal, respectively, where the digital data mentioned above are transmitted in a modulated manner on the first and/or the second driver signal.

A dead time may be provided between the first and the second driver signal to protect the half-bridge circuit from an electrical short. The digital data are transmitted, for example, during the dead time.

That is to say that the digital data are modulated in a signal section of the driver signals, the signal section being located in the dead time. In this case, the digital data or the data signals are encoded in such a way that each data bit of the data signals has 50% high levels and 50% low levels. The data signals are therefore high-frequency compared to the driver signals and may be separated from the driver signals by filtering after the reception of the modulated driver signals. As a result, the data signals do not have a negative effect on switching behavior of the driver signals, even when they are transmitted during the dead time of the driver signals.

The first and the second driver signal may be generated depending on (or from) a pulse-width-modulated control signal. In this case, the first and the second driver signal are generated in a manner shifted with respect to the control signal by a delay time. During this delay time, the digital data are transmitted in a modulated manner on the first and/or the second driver signal.

That is to say that the digital data are modulated in a signal section of the driver signals, the signal section being located in the delay time. The digital data are therefore modulated onto and transmitted on one of the driver signals or the driver signals during the delay time.

Due to the delay time, the driver signals are shifted by an identical period of time with respect to the control signal, where the driver signals (or the adjacent signal sections with high levels of the driver signals) are in turn spaced apart from one another by the dead time.

The delay time may be substantially shorter than the signal period of the pulse-width-modulated control signal or of the driver signals, for example, by a factor of at least 10, 20, 50 or 100. As a result, the delay time is of virtually no consequence compared to the signal period of the driver signals and also does not have a negative effect, or has only a negligibly minor effect on the duty cycle of the driver signals.

In this case, the digital data may be modulated onto the first and/or the second driver signal in such a way that the signal level, the signal level duration and/or the duty cycle of the first and/or the second driver signal can be changed independently of the modulated digital data.

Since the driver signals are generated in an offset manner with respect to the control signal only by the predefined delay time, it is possible to change the signal edge gradient, the signal level, the signal level duration (the duration of the respective signal level) and/or the duty cycle of the driver signals independently of the digital data that is to be modulated or that is modulated.

Another aspect of the disclosure provides a method for operating an electric machine by the positive-voltage-side and the negative-voltage-side semiconductor switch of the half-bridge circuit, where the positive-voltage-side and/or the negative-voltage-side semiconductor switch are operated according to the method described above.

The digital data, which are transmitted in a modulated manner on the first and/or the second driver signal according to the method described above, may include information about switching speed, link circuit voltage, phase currents, operating status and/or operating faults of a converter for operating the electric machine, the information having to be taken into account for the optimum operation of the electric machine or occurring during operation of the electric machine and being able to be detected or measured by suitable sensors.

Another aspect of the disclosure provides a circuit arrangement, for example, a driver circuit, for operating at least one semiconductor switch using at least one pulse-width-modulated driver signal. The circuit arrangement includes a modulator, which is configured to modulate digital data onto the pulse-width-modulated driver signal. In this case, the digital data includes information about measurement variables and/or reference/control variables and/or manipulated variables for operating the semiconductor switch.

The circuit arrangement may be configured to operate a positive-voltage-side and a negative-voltage-side semiconductor switch of a half-bridge circuit using in each case a first and a second pulse-width-modulated driver signal, respectively. In this case, the modulator is further configured to modulate digital data onto the first and/or the second driver signal.

According to another aspect of the disclosure, a converter, such as an inverter, for operating an electric machine is provided. The converter includes at least one half-bridge circuit having a positive-voltage-side and a negative-voltage-side semiconductor switch, and at least one circuit arrangement as described above for operating the positive-voltage-side and/or the negative-voltage-side semiconductor switch. In this case, the circuit arrangement is electrically connected to the control terminal of the respective semiconductor switches by a control signal output in each case.

The converter includes three, six or nine half-bridge circuits having in each case a positive-voltage-side and a negative-voltage-side semiconductor switch, and the circuit arrangement described above for operating the positive-voltage-side and/or the negative-voltage-side semiconductor switches of the half-bridge circuits. To this end, the circuit arrangement has a corresponding number of control signal outputs via which the circuit arrangement is electrically connected to the control terminal of the respective semiconductor switches and controls the corresponding semiconductor switches.

In this case, the circuit arrangement of the converter may further be configured to transmit information about the switching speed, the link circuit voltage, the phase currents, the operating status and/or the operating fault of the converter and/or of the electric machine as digital data on the first and/or the second driver signal in a modulated manner.

Advantageous configurations of the method for operating the semiconductor switches using the pulse-width-modulated driver signals described above are, insofar as they are applicable moreover to the circuit arrangement described above for operating the semiconductor switches or to the method mentioned above or to the converter mentioned above for operating the electric machine, should also be regarded as advantageous configurations of the circuit arrangement, the method and the converter for operating the electric machine.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a schematic illustration of a circuit topology of an inverter for operating an electric machine;

FIGS. 2A, 2B show schematic signal diagrams of a pulse-width-modulated control signal and pulse-width-modulated driver signals without and with modulated digital data.

Like reference symbols in the various drawings indicate like elements.

### DETAILED DESCRIPTION

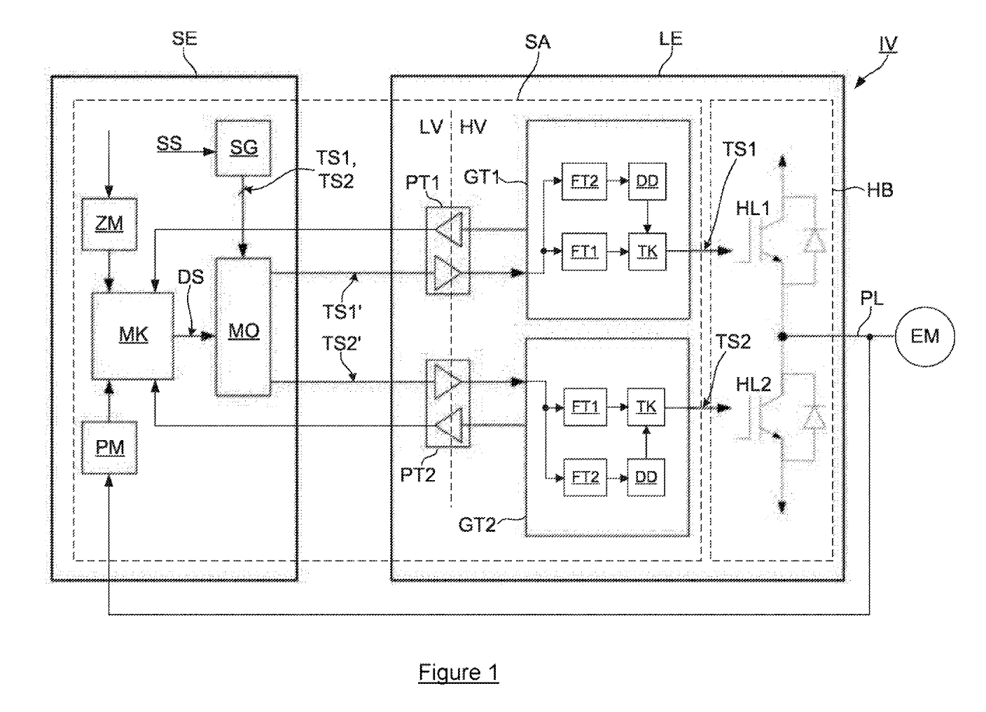

FIG. 1 shows an inverter IV (or a part thereof) for operating an electric machine EM. The inverter IV includes a power output stage having three half-bridge circuits HB designed substantially identically to one another, which are electrically connected in parallel with one another and are electrically connected between a positive and a negative supply power line. For the simple illustration of the inverter IV, FIG. 1 depicts, by way of example, only one of the three half-bridge circuits HB. The half-bridge circuits HB each include a positive-voltage-side semiconductor switch HL1 and a negative-voltage-side semiconductor switch HL2. The semiconductor switches HL1, HL2 are connected in series with one another in the respective half-bridge circuits HB and are electrically connected directly to one of three stator windings of the electric machine EM by a respective phase line PL, which is electrically connected to a terminal point between the semiconductor switches HL1, HL2 of the respective half-bridge circuits HB.

The inverter IV further includes a circuit arrangement SA for actuating the semiconductor switches HL1, HL2. The circuit arrangement SA includes six gate drivers GT1, GT2 designed substantially analogously to one another, the gate drivers being designed to actuate the six semiconductor switches HL1, HL2. The gate drivers GT1, GT2 are electrically connected to the gate terminal of the respective semiconductor switches HL1, HL2, in each case, via a signal output. For the simple illustration of the inverter IV, FIG. 1 depicts by way of example only two gate drivers GT1, GT2 for actuating a positive-voltage-side semiconductor switch HL1 and a negative-voltage-side semiconductor switch HL2 of one of the three half-bridge circuits HB. The gate drivers GT1, GT2 are located on a high-voltage side HV of the circuit arrangement SA in which a voltage level of, for example, 48 V is present.

The circuit arrangement SA further includes six potential dividers PT1, PT2 designed substantially analogously to one another. The potential dividers each having two signal inputs and two signal outputs. The potential dividers PT1, PT2 are each electrically connected to a further signal output of the respective gate drivers GT1, GT2, in each case, via a signal input. The potential dividers PT1, PT2 are each electrically connected to a signal input of the respective gate drivers GT1, GT2 in each case via a signal output. The potential dividers PT1, PT2 are each electrically connected to a signal output of a signal modulator MO to be described below in each case via a further signal input. The potential dividers PT1, PT2 are each electrically connected to a signal input of a microcontroller (control board) MK to be described below in each case via a further signal output. For the simple illustration of the inverter IV, FIG. 1 depicts, by way of example, only two potential dividers PT1, PT2, which are each electrically connected to a gate driver GT1 for actuating a positive-voltage-side semiconductor switch HL1 and to a gate driver GT2 for actuating a negative-voltage-side semiconductor switch HL2 of a half-bridge circuit HB, respectively.

The potential dividers PT1, PT2 are configured to DC-isolate the electrical potentials between the aforementioned high-voltage side HV and a low-voltage side LV of the circuit arrangement SA in which a voltage level of, for example, 12 volts is present, and therefore to protect the circuit arrangement SA and the components thereof from overvoltages.

The circuit arrangement SA further includes the aforementioned signal modulator MO, which is electrically connected to the signal input of the respective potential dividers PT1, PT2, in each case, via a signal output. The mode of operation of the signal modulator MO is described below.

The circuit arrangement SA further includes a signal generator SG, the signal-output side of which is electrically connected to a signal input of the signal modulator MO. The signal generator SG is configured to generate six pulse-width-modulated driver signals TS1, TS2 from a pulse-width-modulated control signal SS, the six semiconductor switches HL1, HL2 being operated in a controlled manner by the driver signals.

The circuit arrangement SA further includes the aforementioned microcontroller MK, which is electrically connected to a further signal input of the signal modulator MO via a signal output. The mode of operation of the microcontroller MK is described below.

The circuit arrangement SA further comprises a link circuit voltmeter ZM, which is electrically connected to a further signal input of the microcontroller MK via a signal output. The link circuit voltmeter ZM is electrically connected on the input side to two current terminals of a link circuit capacitor (not illustrated in FIG. 1) of the inverter IV and is configured, during operation of the electric machine EM, to measure the link circuit voltage at the link circuit capacitor and to transfer the measured link circuit voltage value to the microcontroller MK via the signal output.

The circuit arrangement SA further includes a phase current meter PM, which is electrically connected to a further signal input of the microcontroller MK via a signal output. The phase current meter PM is electrically connected on the input side to the phase line PL and is configured, during operation of the electric machine EM, to measure the phase current flowing through the phase line PL and to transfer the measured phase current value to the microcontroller MK via the signal output.

The circuit arrangement SA may have further measuring units, which are configured to measure further operating parameters, such as temperatures, for example, and/or to detect the operating state or the operating faults at the electric machine EM or at the inverter IV and are electrically connected in each case to a further signal input of the microcontroller MK via their respective signal output. These measuring units are configured, during operation of the electric machine EM, to detect the corresponding operating parameters, the corresponding operating state, or the operating faults and to transfer the corresponding (measurement) values to the microcontroller MK.

The gate drivers GT1, GT2 and further power electronics components located on the high-voltage side HV of the circuit arrangement SA form, together with the semiconductor switches HL1, HL2, a power electronics unit LE.

The circuit components, such as the signal modulator MO, the signal generator SG and the microcontroller MK, for example, located on the low-voltage side LV of the circuit arrangement SA, together form a central control board SE.

The low-voltage side LV is DC-isolated from the high-voltage side HV by the potential dividers PT1, PT2.

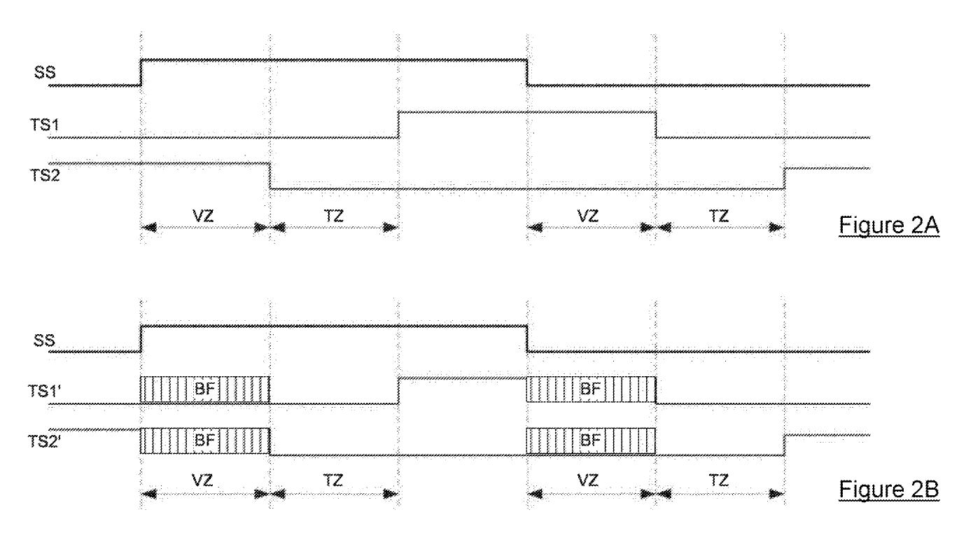

After the circuit topology of the inverter IV has been described with reference to FIG. 1, the mode of operation of the inverter IV will be described in detail below with reference to FIGS. 2A, 2B.

In order that the electric machine EM can be operated in a low-loss and fault-free manner, the semiconductor switches HL1, HL2 of the power output stage have to be actuated depending on various parameters that are identified based on the information about required switching speed, link circuit voltage, phase currents, operating status of the electric machine EM and/or operating faults in the inverter IV or in the electric machine EM. To this end, the relevant information has to be detected in the form of measurement values and transferred to the gate drivers GT1, GT2 as digital data such that the gate drivers GT1, GT2 can accordingly regulate and optimize the actuation of the semiconductor switches HL1, HL2 depending on this information.

In order to overcome this without additional outlay or with the lowest possible additional outlay, the microcontroller MK is configured to analyze, in a manner known to those skilled in the art, measurement values. The microcontroller MK receives the measurement values from the link circuit voltmeter ZM, the phase current meter PM and the further measuring units via the signal inputs, and information about the operating status or operating faults, which the microcontroller MK receives in the form of further measurement values from the gate drivers GT1, GT2 via the further signal inputs. The microcontroller MK is also configured to generate digital data based on these measurement values, the driver signals TS1, TS2 being adjusted based on the digital data for actuating the semiconductor switches HL1, HL2. The microcontroller MK transmits the digital data in the form of digital signals DS to the signal modulator MO.

The signal generator SG generates pulse-width-modulated driver signals TS1, TS2 from a pulse-width-modulated control signal SS. In this case, the signal generator SG generates the driver signals TS1, TS2 in such a way that, for actuation by the positive-voltage-side and the negative-voltage-side semiconductor switch HL1, HL2 of respective half-bridge circuits HB, the driver signals TS1, TS2 have a dead time TZ with respect to one another. The signal generator SG also generates the driver signals TS1, TS2 in such a way that all the driver signals TS1, TS2 are shifted with respect to the control signal SS by a prescribed delay time VZ. The dead time TZ and the delay time VZ are illustrated in FIG. 2A. The signal generator SG then transfers the driver signals TS1, TS2 to the signal modulator MO.

The signal modulator MO modulates the digital signals DS onto the driver signals TS1, TS2 by modulating the digital data, which are included in the digital signals DS, into the respective signal sections in the form of high-frequency bit sequences BF, the signal sections being located in the delay times VZ of the comparatively low-frequency driver signals TS1, TS2. In this case, the corresponding signal sections are simply “replaced” by the digital bit sequences BF of the digital signal DS, as is illustrated in FIG. 2B.

The signal modulator MO then transfers the driver signals TS1′, TS2′ modulated with the digital signals DS to the gate drivers GT1, GT2 via the potential dividers PT1, PT2.

The gate drivers GT1, GT2 separate the digital signals DS or the digital data from the respective driver signals TS1′, TS2′ by a demodulation method known to those skilled in the art.

To this end, the gate drivers GT1, GT2 each include a first filter FT1 for filtering the driver signals TS1, TS2 from the received modulated driver signals TS1′, TS2′ and each include a second filter FT2 for filtering the data signals DS from the modulated driver signals TS1′, TS2′. The filters FT1, FT2 are electrically connected on the input side to the input of the respective gate drivers GT1, GT2.

The gate drivers GT1, GT2 each further includes a data decoder DD for decoding the digital data from the respective digital signals DS obtained through the filtering. The data decoders DD are electrically connected on the signal-input side to a signal output of the respective second filters FT2.

The gate drivers GT1, GT2 also each include a driver signal controller TK for adjusting the respective driver signals TS1, TS2 obtained through the filtering depending on the decoded digital data. The driver signal controllers TK are electrically connected on the signal-input side to a signal output of the respective first filters FT1 via a signal input. The driver signal controllers TK are also electrically connected on the signal-input side to a further signal output of the respective data decoders DD via a further signal input.

During operation of the electric machine EM, the respective first filters FT1 of the respective gate drivers GT1, GT2 filter out the respective driver signals TS1, TS2 from the received modulated driver signals TS1′, TS2′ and transfer them to the driver signal controller TK. At the same time, the respective second filters FT2 of the respective gate drivers GT1, GT2 filter out the respective data signals DS from the same modulated driver signals TS1′, TS2′ and transfer them to the corresponding data decoders DD. The data decoders DD decode the data signals DS and obtain from the digital data included in the data signals DS1, DS2 useful information about how the driver signals TS1, TS2 need to be adjusted in order, for example, to operate the electric machine EM efficiently or to fix the operating faults in the electric machine EM.

To prevent data errors, the data decoders DD perform a parity check here before they filter out the needed information from the digital data. The parity is checked in a manner known to those skilled in the art, such as, for example, by multiple sampling of the digital signals DS or based on parity check codes, which have been inserted into the data signals DS by the signal modulator MO during the modulation phase.

The data decoders DD then pass the useful information on to the respective driver signal controllers TK. The driver signal controllers TK then adjust the respective filtered driver signals TS1, TS2 based on the useful information and pass the adjusted driver signals TS1, TS2 on to the gate terminals of the corresponding semiconductor switches HL1, HL2 via the respective signal outputs and thus control the semiconductor switches HL1, HL2 accordingly.

The transmitted digital data may include, inter alia: link circuit information, such as link circuit voltage, for example, which is measured at the link circuit capacitor; phase current information, such as phase current values, for example, which are measured at the phase lines PL; commands, which, in the event of a fault in the semiconductor switches HL1, HL2 or in the inverter IV, are transmitted as digital data. In the presence of such a command, the semiconductor switches HL1, HL2 are moved into a diagnosis mode, for example.

In some examples, it is possible to use the link circuit information, such as the link circuit voltage measured at the link circuit capacitor, to identify how high the overvoltage peaks are during the preceding switching phases of the semiconductor switches HL1, HL2. This in turn gives some indication about how fast the semiconductor switches HL1, HL2 may be switched on/off without dangerous overvoltage peaks arising in the process.

If the measured link circuit voltage is far below a prescribed maximum permitted reference link circuit voltage, the signal edges of the driver signals TS1, TS2 (based on the useful information obtained from the digital data) can be set to be steeper and the switching processes of the semiconductor switches HL1, HL2 can therefore be performed faster. The switching losses are reduced and the overall efficiency of the inverter is increased thereby.

In contrast, if the measured link circuit voltage is close to the prescribed reference link circuit voltage and an overvoltage in the inverter IV is imminent, the signal edges of the driver signals TS1, TS2 (based on the useful information) can be set to be flatter and the switching processes of the semiconductor switches HL1, HL2 can therefore be performed more slowly. This prevents an imminent danger caused by overvoltage. As a result, the lifetime of the semiconductor switches HL1, HL2 and thus of the inverter IV is extended.

Based on phase current information, such as, on the phase currents measured on the phase lines PL, the switch-on behaviors of the semiconductor switches HL1, HL2 are optimized and the switching losses in the semiconductor switches HL1, HL2 and the instances of EMC (electromagnetic compatibility) interference are reduced.

Based on fault signals, which the microcontroller MK receives via the status line, the microcontroller MK generates corresponding digital signals DS, which move the gate drivers GT1, GT2 and hence also the semiconductor switches HL1, HL2 into a predefined diagnosis mode, during which the precise type and the location of the fault may be identified in a manner known to those skilled in the art.

Virtually cost-neutral augmented communication between the gate drivers GT1, GT2 and the microcontroller MK is possible using the circuit arrangement SA described above. The switching losses may be significantly reduced by the mode of operation described above. The EMC behaviors of the semiconductor switches HL1, HL2 are also improved. Diagnosis options are also augmented, which contributes to increased availability of the entire system.

The filter time of the filters FT1, FT2 and the duration of the data decoding in the data decoder DD are coordinated with one another in such a way that there are no time delays and also no signal distortions in the driver signals TS1, TS2. For example, the filter times of the second filters FT2 for filtering the data signals DS are set to be shorter than those of the first filters FT1 for filtering the driver signals TS1, TS2.

The sequences of the filtering, the data decoding and the adaptation of the driver signals TS1, TS2 may be synchronized with the aid of predefined start bits (such as in the case of an edge change or a specific sequence of edge changes in the driver signals TS1, TS2, for example) that are incorporated in the data decoder DD, where, in the presence of the start bits, the control paths or the signal outputs of the corresponding gate drivers GT1, GT2 can initially be locked.

This ensures that the changing of edges or levels of the start bits does not have an effect on the actuation of the semiconductor switches HL1, HL2. Only when all bits of the digital data have been received (by identification of predefined stop bits) are the control paths or the corresponding signal outputs of the corresponding gate drivers GT1, GT2 released again.

The actuation is unchanged, or only changed to a negligibly small degree, with respect to conventional actuation due to the intelligent decoding method described above in the gate drivers GT1, GT2, such that there are no negative effects, such as increased jitter effects or reduced switching dynamics, for example.

A number of implementations have been described. Nevertheless, it will be understood that various modifications may be made without departing from the spirit and scope of the disclosure. Accordingly, other implementations are within the scope of the following claims.

What is claimed is:

1. A method for operating at least one semiconductor switch using at least one pulse-width-modulated driver signal, the method comprising:
transmitting digital data in a modulated manner on the pulse-width-modulated driver signal, the digital data including information about measurement variables and/or reference/control variables and/or manipulated variables for operating the semiconductor switch.

2. The method of claim 1, wherein the at least one semiconductor switch includes a positive-voltage-side and a negative-voltage-side semiconductor switch of a half-bridge circuit, and wherein the method comprises:
operating, using a first and a second pulse-width-modulated driver signal, the positive-voltage-side and/or the negative-voltage-side semiconductor switch respectively,
transmitting, the digital data in a modulated manner on the first and/or the second driver signal.

3. The method of claim 1, further comprising:
providing a dead time between the first and the second driver signal; and
transmitting the digital data during the dead time.

4. The method of claim 1, further comprising:
generating the first and the second driver signal based on a pulse-width-modulated control signal;
shifting the first and the second driver signals with respect to the control signal by a delay time; and
transmitting the digital data in a modulated manner on the first and/or the second driver signal during the delay time.

5. A method for operating an electric machine by a positive-voltage-side and a negative-voltage-side semiconductor switch of a half-bridge circuit, the method includes:
providing, first and second pulse-width-modulated driver signals;
transmitting digital data in a modulated manner on the first and/or the second pulse-width-modulated driver signal, the digital data including information about measurement variables and/or reference/control variables and/or manipulated variables for operating the semiconductor switch; and
receiving at the positive-voltage-side and the negative-voltage-side semiconductor switch the first and second pulse-width-modulated driver signals respectively.

6. The method of claim 5, wherein the digital data further includes information about switching speed, link circuit voltage, phase currents, operating status and/or operating faults for or during operation of the electric machine.

7. A circuit arrangement for operating at least one semiconductor switch using at least one pulse-width-modulated driver signal, the circuit arrangement comprising:
a modulator configured to modulate digital data onto the pulse-width-modulated driver signal, the digital data including information about measurement variables and/or reference/control variables and/or manipulated variables for operating the semiconductor switch; and
at least one semiconductor switch receiving the at least one pulse-width-modulation driver signal.

8. The circuit arrangement of claim 7, further comprising:
a positive-voltage-side semiconductor switch of a half-bridge circuit;
a negative-voltage-side semiconductor switch of the half-bridge circuit;
a first pulse-width-modulated driver signal for operating the positive-voltage-side semiconductor switch; and
a second pulse-width-modulated driver signal for operating the negative-voltage-side semiconductor switch,
wherein the modulator modulates digital data onto the first and/or the second driver signal.

9. A converter for operating an electric machine, the converter comprising:
at least one half-bridge circuit having a positive-voltage-side and a negative-voltage-side semiconductor switch; and
at least one circuit arrangement for operating the positive-voltage-side and/or the negative-voltage-side semiconductor switch using at least one pulse-width-modulated driver signal, the circuit arrangement comprising:
a modulator modulating digital data onto the pulse-width-modulated driver signal, the digital data including information about measurement variables and/or reference/control variables and/or manipulated variables for operating the semiconductor switch; and
at least one semiconductor switch receiving the at least one pulse-width-modulation driver signal.

10. The converter of claim 9, further comprising:
a positive-voltage-side semiconductor switch of a half-bridge circuit;
a negative-voltage-side semiconductor switch of the half-bridge circuit;
a first pulse-width-modulated driver signal for operating the positive-voltage-side semiconductor switch; and
a second pulse-width-modulated driver signal for operating the negative-voltage-side semiconductor switch, wherein the modulator modulates digital data onto the first and/or the second driver signal.
